(19) United States
(12) Patent Application Publication
(10) Pub. No.: US 2019/0066788 A1
(43) Pub. Date: Feb. 28, 2019

(54) REDUCED ROUTING SIGNALS

(71) Applicant: SanDisk Technologies LLC, Plano, TX (US)

(72) Inventors: KENNETH LOUIE, Sunnyvale, CA (US); QUI NGUYEN, San Jose, CA (US)

(73) Assignee: SanDisk Technologies LLC, Plano, TX (US)

(21) Appl. No.: 15/692,869

(22) Filed: Aug. 31, 2017

(51) Int. Cl. G11C 16/08; G11C 16/04

(52) U.S. Cl. CPC G11C 16/08; G11C 16/04

(57) ABSTRACT

Apparatuses, systems, methods, and computer program products are disclosed for reduced routing signals. An apparatus includes a generator circuit that generates switch gate voltages for two or more word line switches. Two or more word line switches are on opposite sides of an array of memory elements and are for coupling word line voltages to word lines. An apparatus includes a word line switch circuit that supplies switch gate voltages to two or more word line switches. An apparatus includes a transistor control circuit that supplies select gate voltages to two or more select gates. Two or more select gates control select gate drain transistors. Select gate voltages are different from switch gate voltages. Select gate voltages and switch gate voltages are both based on a routing line voltage on a routing line that extends across an array of memory elements.

### TECHNICAL FIELD

The present disclosure, in various embodiments, relates to routing signals for performing operations and more particularly relates to reducing a number of routing signals for performing operations.

### BACKGROUND

Many electrical circuits and devices, such as data storage devices or the like, use routing signals. Routing signals may be used to carry voltages from one physical location to another physical location in an electric circuit, for example. There may be a limited amount of space in an electric circuit for a number of routing signals.

### SUMMARY

Apparatuses are presented for reduced routing signals. In one embodiment, an apparatus includes a generator circuit that generates switch gate voltages for two or more word line switches. In some embodiments, two or more word line switches are on opposite sides of an array of memory elements and are for coupling word line voltages to word lines. An apparatus, in certain embodiments, includes a word line switch circuit that supplies switch gate voltages to two or more word line switches. An apparatus, in one embodiment, includes a transistor control circuit that supplies select gate voltages to two or more select gates. In various embodiments, two or more select gates control select gate drain transistors. In certain embodiments, select gate voltages are different from switch gate voltages. In some embodiments, select gate voltages and switch gate voltages are both based on a routing line voltage on a routing line that extends across an array of memory elements.

An apparatus, in certain embodiments, includes a shift circuit that increases a routing line voltage and produces switch gate voltages in response to the routing line voltage indicating a logic high value. In some embodiments, an apparatus includes an inverter circuit that inverts a routing line voltage to produce select gate voltages. An apparatus, in one embodiment, includes an inverter circuit that inverts a routing line voltage to produce an inverted voltage. In various embodiments, an apparatus includes a shift circuit that increases an inverted voltage and produces switch gate voltages in response to the inverted voltage indicating a logic high value. In some embodiments, switch gate voltages are greater than 20 volts and select gate voltages are less than 3 volts. In various embodiments, switch gate voltages are less than 3 volts and select gate voltages are greater than 20 volts. In certain embodiments, switch gate voltages are less than 3 volts and select gate voltages are less than 3 volts. In some embodiments, a routing line voltage on a routing line is less than 3 volts.

Systems are presented for reduced routing signals. A system, in one embodiment, includes an array of storage elements. In various embodiments, a system includes two or more word line switches disposed on different sides of an array. In some embodiments, a system includes a block select routing line extending over two or more word line switches and an array in a different plane than the array and between different sides of the array. In certain embodiments, a system includes two or more level shifters coupled to opposite ends of a block select routing line. In one embodiment, a block select gate voltage is supplied to word line switch gates of two or more word line switches based on a routing line voltage on a block select routing line. In various embodiments, an inverse polarity block select gate voltage is supplied to select gates of two or more transistors based on a routing line voltage on a block select routing line.

In certain embodiments, two or more level shifters increase a routing line voltage carried by a block select routing line to produce a block select gate voltage in response to the routing line voltage indicating a logic high. In various embodiments, a routing line voltage is increased from less than 3 volts to greater than 25 volts in response to the routing line voltage indicating a logic high. In some embodiments, a system includes two or more inverters. In certain embodiments, two or more inverters invert a routing line voltage carried by a block select routing line to produce an inverse polarity block select gate voltage. In one embodiment, a system includes two or more inverters. In some embodiments, two or more inverters invert a routing line voltage carried by a block select routing line to produce an inverted voltage. In various embodiments, two or more level shifters increase an inverted voltage to produce an inverse polarity block select gate voltage in response to the inverted voltage indicating a logic high. In some embodiments, an inverse polarity block select gate voltage is increased from less than 3 volts to greater than 25 volts in response to an inverted voltage indicating a logic high. In one embodiment, a block select gate voltage is greater than 25 volts and an inverse polarity block select gate voltage is less than 3 volts. In various embodiments, a block select gate voltage is less than 3 volts and an inverse polarity block select gate voltage is greater than 25 volts. In some embodiments, a routing line voltage carried by a block select routing line is less than 3 volts.

An apparatus for reduced routing signals, in one embodiment, includes means for supplying a block select gate voltage to a plurality of word line switch gates based on a routing line voltage on a single routing line that extends across an array of memory elements. In some embodiments, an apparatus includes means for supplying an inverse polarity block select gate voltage to a plurality of select gates without a routing line separate from a single routing line.

### BRIEF DESCRIPTION OF THE DRAWINGS

A more particular description is included below with reference to specific embodiments illustrated in the appended drawings. Understanding that these drawings depict only certain embodiments of the disclosure and are not therefore to be considered to be limiting of its scope, the disclosure is described and explained with additional specificity and detail through the use of the accompanying drawings, in which:

FIG. 1A is a schematic block diagram illustrating one embodiment of a system for reduced routing signals;

FIG. 1B is a schematic block diagram illustrating another embodiment of a system for reduced routing signals;

FIG. 2 is a schematic block diagram illustrating one embodiment of a string of storage cells;

FIG. 3 is a schematic block diagram illustrating one embodiment of an array of storage cells;

FIG. 4 illustrates one embodiment of a 3D, vertical NAND flash memory structure;

FIG. 5 is a schematic block diagram illustrating one embodiment of a routing reduction component;

FIG. 6 is a schematic block diagram illustrating a further embodiment of a routing reduction component;

FIG. 7 is a schematic block diagram illustrating a further embodiment of a system for reduced routing signals;

FIG. 8 is a circuit diagram illustrating one embodiment of a circuit for reduced routing signals;

FIG. 9 is a circuit diagram illustrating another embodiment of a circuit for reduced routing signals; and

FIG. 10 is a schematic flow chart diagram illustrating one embodiment of a method for reduced routing signals.

### DETAILED DESCRIPTION

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “circuit,” “module,” “apparatus,” or “system.” Furthermore, aspects of the present disclosure may take the form of a computer program product embodied in one or more non-transitory computer readable storage media storing computer readable and/or executable program code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like.

Modules may also be implemented at least partially in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may include a single instruction, or many instructions, and may even be distributed over several different code segments, among different programs, across several memory devices, or the like. Where a module or portions of a module are implemented in software, the software portions may be stored on one or more computer readable and/or executable storage media. Any combination of one or more computer readable storage media may be utilized. A computer readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may alternatively be embodied by or implemented as a component.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

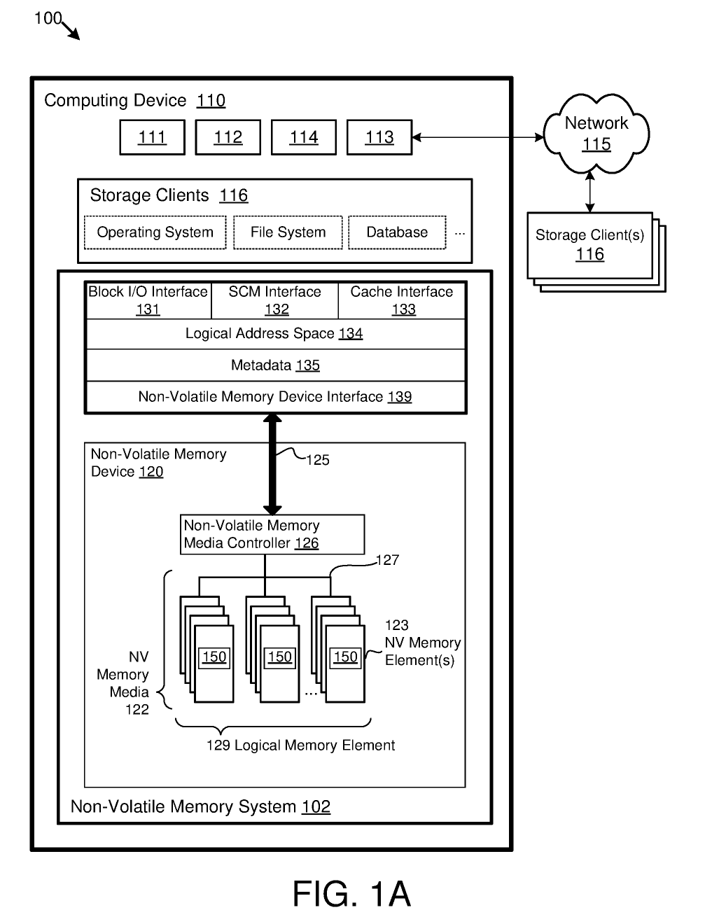

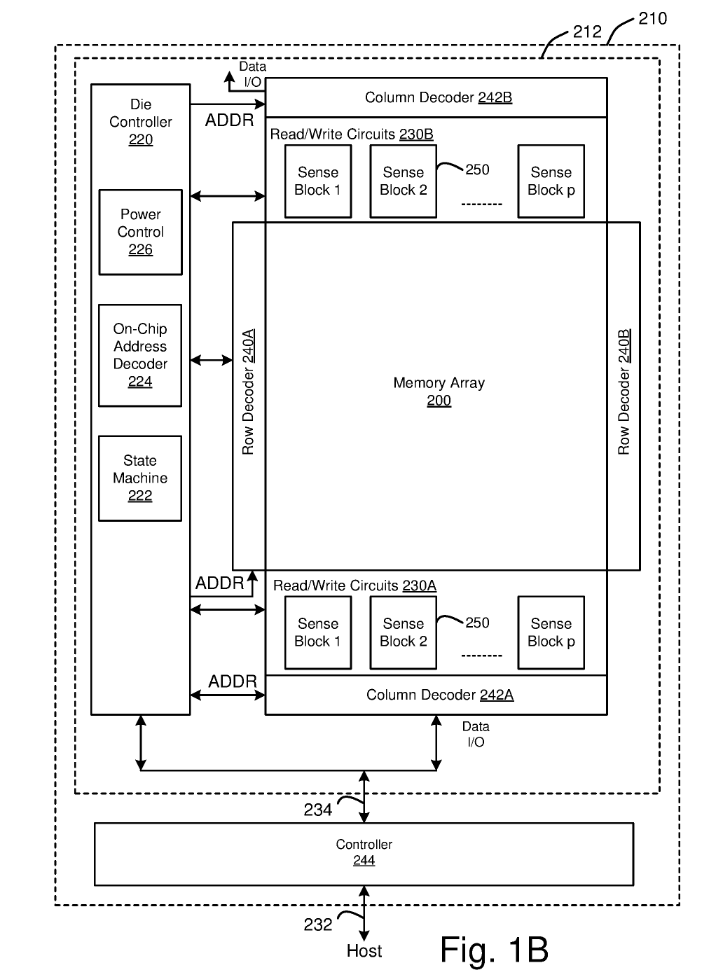

FIG. 1A is a block diagram of one embodiment of a system 100 comprising a routing reduction component 150 for a non-volatile memory device 120. The routing reduction component 150 may be part of and/or in communication with a non-volatile memory element 123, or the like. The routing reduction component 150 may operate on a non-volatile memory system 102 of a computing device 110, which may comprise a processor 111, volatile memory 112, and a communication interface 113. The processor 111 may comprise one or more central processing units, one or more general-purpose processors, one or more application-specific processors, one or more virtual processors (e.g., the computing device 110 may be a virtual machine operating within a host), one or more processor cores, or the like. The communication interface 113 may comprise one or more network interfaces configured to communicatively couple the computing device 110 and/or non-volatile memory controller 126 to a communication network 115, such as an Internet Protocol (IP) network, a Storage Area Network (SAN), wireless network, wired network, or the like.

The non-volatile memory device 120, in various embodiments, may be disposed in one or more different locations relative to the computing device 110. In one embodiment, the non-volatile memory device 120 comprises one or more non-volatile memory elements 123, such as semiconductor chips or packages or other integrated circuit devices disposed on one or more printed circuit boards, storage housings, and/or other mechanical and/or electrical support structures. For example, the non-volatile memory device 120 may comprise one or more direct inline memory module (DIMM) cards, one or more expansion cards and/or daughter cards, a solid-state-drive (SSD) or other hard drive device, and/or may have another memory and/or storage form factor. The non-volatile memory device 120 may be integrated with and/or mounted on a motherboard of the computing device 110, installed in a port and/or slot of the computing device 110, installed on a different computing device 110 and/or a dedicated storage appliance on the network 115, in communication with the computing device 110 over an external bus (e.g., an external hard drive), or the like.

The non-volatile memory device 120, in one embodiment, may be disposed on a memory bus of a processor 111 (e.g., on the same memory bus as the volatile memory 112, on a different memory bus from the volatile memory 112, in place of the volatile memory 112, or the like). In a further embodiment, the non-volatile memory device 120 may be disposed on a peripheral bus of the computing device 110, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the non-volatile memory device 120 may be disposed on a data network 115, such as an Ethernet network, an Infiniband network, SCSI RDMA over a network 115, a storage area network (SAN), a local area network (LAN), a wide area network (WAN) such as the Internet, another wired and/or wireless network 115, or the like.

The computing device 110 may further comprise a non-transitory, computer readable storage medium 114. The computer readable storage medium 114 may comprise executable instructions configured to cause the computing device 110 (e.g., processor 111) to perform steps of one or more of the methods disclosed herein.

The non-volatile memory system 102, in the depicted embodiment, includes a routing reduction component 150. The routing reduction component 150, in one embodiment, is configured to generate switch gate voltages for two or more word line switches. In some embodiments, the routing reduction component 150 includes two or more word line switches on opposite sides of an array of memory elements and used for coupling word line voltages to word lines for the non-volatile memory device 120 described below. The routing reduction component 150, in certain embodiments, may supply switch gate voltages to two or more word line switches. The routing reduction component 150 may also supply select gate voltages to two or more select gates. In various embodiments, two or more select gates control select gate drain transistors. In certain embodiments, select gate voltages are different from switch gate voltages. In some embodiments, select gate voltages and switch gate voltages are both based on a routing line voltage on a routing line that extends across an array of memory elements. Thus, routing reduction may be performed.

In one embodiment, the routing reduction component 150 may comprise logic hardware of one or more non-volatile memory devices 120, such as a non-volatile memory media controller 126, a non-volatile memory element 123, a device controller, a field-programmable gate array (FPGA) or other programmable logic, firmware for an FPGA or other programmable logic, microcode for execution on a microcontroller, an application-specific integrated circuit (ASIC), or the like. In another embodiment, the routing reduction component 150 may comprise executable software code, such as a device driver or the like, stored on the computer readable storage medium 114 for execution on the processor 111. In a further embodiment, the routing reduction component 150 may include a combination of both executable software code and logic hardware.

A device driver and/or the non-volatile memory media controller 126, in certain embodiments, may present a logical address space 134 to the storage clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

A device driver for the non-volatile memory device 120 may maintain metadata 135, such as a logical to physical address mapping structure, to map logical addresses of the logical address space 134 to media storage locations on the non-volatile memory device(s) 120. A device driver may be configured to provide storage services to one or more storage clients 116. The storage clients 116 may include local storage clients 116 operating on the computing device 110 and/or remote, storage clients 116 accessible via the network 115 and/or network interface 113. The storage clients 116 may include, but are not limited to: operating systems, file systems, database applications, server applications, kernel-level processes, user-level processes, applications, and the like.

A device driver may be communicatively coupled to one or more non-volatile memory devices 120. The one or more non-volatile memory devices 120 may include different types of non-volatile memory devices including, but not limited to: solid-state storage devices, semiconductor storage devices, SAN storage resources, or the like. The one or more non-volatile memory devices 120 may comprise one or more respective non-volatile memory media controllers 126 and non-volatile memory media 122. A device driver may provide access to the one or more non-volatile memory devices 120 via a traditional block I/O interface 131. Additionally, a device driver may provide access to enhanced functionality through the SCM interface 132. The metadata 135 may be used to manage and/or track data operations performed through any of the Block I/O interface 131, SCM interface 132, cache interface 133, or other, related interfaces.

The cache interface 133 may expose cache-specific features accessible via a device driver for the non-volatile memory device 120. Also, in some embodiments, the SCM interface 132 presented to the storage clients 116 provides access to data transformations implemented by the one or more non-volatile memory devices 120 and/or the one or more non-volatile memory media controllers 126.

A device driver may present a logical address space 134 to the storage clients 116 through one or more interfaces. As discussed above, the logical address space 134 may comprise a plurality of logical addresses, each corresponding to respective media locations of the one or more non-volatile memory devices 120. A device driver may maintain metadata 135 comprising any-to-any mappings between logical addresses and media locations, or the like.

A device driver may further comprise and/or be in communication with a non-volatile memory device interface 139 configured to transfer data, commands, and/or queries to the one or more non-volatile memory devices 120 over a bus 125, which may include, but is not limited to: a memory bus of a processor 111, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The non-volatile memory device interface 139 may communicate with the one or more non-volatile memory devices 120 using input-output control (IO-CTL) command(s), IO-CTL command extension(s), remote direct memory access, or the like.

The communication interface 113 may comprise one or more network interfaces configured to communicatively couple the computing device 110 and/or the non-volatile memory controller 126 to a network 115 and/or to one or more remote, network-accessible storage clients 116. The storage clients 116 may include local storage clients 116 operating on the computing device 110 and/or remote, storage clients 116 accessible via the network 115 and/or the network interface 113. The non-volatile memory controller 126 is part of and/or in communication with one or more non-volatile memory devices 120. Although FIG. 1A depicts a single non-volatile memory device 120, the disclosure is not limited in this regard and could be adapted to incorporate any number of non-volatile memory devices 120.

The non-volatile memory device 120 may comprise one or more elements 123 of non-volatile memory media 122, which may include but is not limited to: ReRAM, Memristor memory, programmable metallization cell memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like. The one or more elements 123 of non-volatile memory media 122, in certain embodiments, comprise storage class memory (SCM).

While legacy technologies such as NAND flash may be block and/or page addressable, storage class memory, in one embodiment, is byte addressable. In further embodiments, storage class memory may be faster and/or have a longer life (e.g., endurance) than NAND flash; may have a lower cost, use less power, and/or have a higher storage density than DRAM; or offer one or more other benefits or improvements when compared to other technologies. For example, storage class memory may comprise one or more non-volatile memory elements 123 of ReRAM, Memristor memory, programmable metallization cell memory, phase-change memory, nano RAM, nanocrystal wire-based memory, silicon-oxide based sub-10 nanometer process memory, graphene memory, SONOS memory, PMC memory, CBRAM, MRAM, and/or variations thereof.

While the non-volatile memory media 122 is referred to herein as “memory media,” in various embodiments, the non-volatile memory media 122 may more generally comprise one or more non-volatile recording media capable of recording data, which may be referred to as a non-volatile memory medium, a non-volatile storage medium, or the like. Further, the non-volatile memory device 120, in various embodiments, may comprise a non-volatile recording device, a non-volatile memory device, a non-volatile storage device, or the like.

The non-volatile memory media 122 may comprise one or more non-volatile memory elements 123, which may include, but are not limited to: chips, packages, planes, die, or the like. A non-volatile memory media controller 126 may be configured to manage data operations on the non-volatile memory media 122, and may comprise one or more processors, programmable processors (e.g., FPGAs), ASICs, micro-controllers, or the like. In some embodiments, the non-volatile memory media controller 126 is configured to store data on and/or read data from the non-volatile memory media 122, to transfer data to/from the non-volatile memory device 120, and so on.

The non-volatile memory media controller 126 may be communicatively coupled to the non-volatile memory media 122 by way of a bus 127. The bus 127 may comprise an I/O bus for communicating data to/from the non-volatile memory elements 123. The bus 127 may further comprise a control bus for communicating addressing and other command and control information to the non-volatile memory elements 123. In some embodiments, the bus 127 may communicatively couple the non-volatile memory elements 123 to the non-volatile memory media controller 126 in parallel. This parallel access may allow the non-volatile memory elements 123 to be managed as a group, forming a logical memory element 129. The logical memory element may be partitioned into respective logical memory units (e.g., logical pages) and/or logical memory divisions (e.g., logical blocks). The logical memory units may be formed by logically combining physical memory units of each of the non-volatile memory elements.

The non-volatile memory controller 126 may organize a block of word lines within a non-volatile memory element 123, in certain embodiments, using addresses of the word lines, such that the word lines are logically organized into a monotonically increasing sequence (e.g., decoding and/or translating addresses for word lines into a monotonically increasing sequence, or the like). In a further embodiment, word lines of a block within a non-volatile memory element 123 may be physically arranged in a monotonically increasing sequence of word line addresses, with consecutively addressed word lines also being physically adjacent (e.g., WL0, WL1, WL2, . . . WLN).

The non-volatile memory controller 126 may comprise and/or be in communication with a device driver executing on the computing device 110. A device driver may provide storage services to the storage clients 116 via one or more interfaces 131, 132, and/or 133. In some embodiments, a device driver provides a block-device I/O interface 131 through which storage clients 116 perform block-level I/O operations. Alternatively, or in addition, a device driver may provide a storage class memory (SCM) interface 132, which may provide other storage services to the storage clients 116. In some embodiments, the SCM interface 132 may comprise extensions to the block device interface 131 (e.g., storage clients 116 may access the SCM interface 132 through extensions or additions to the block device interface 131). Alternatively, or in addition, the SCM interface 132 may be provided as a separate API, service, and/or library. A device driver may be further configured to provide a cache interface 133 for caching data using the non-volatile memory system 102.

A device driver may further comprise a non-volatile memory device interface 139 that is configured to transfer data, commands, and/or queries to the non-volatile memory media controller 126 over a bus 125, as described above.

FIG. 1B illustrates an embodiment of a non-volatile storage device 210 that may include one or more memory die or chips 212. Memory die 212, in some embodiments, includes an array (two-dimensional or three dimensional) of memory cells 200, die controller 220, and read/write circuits 230A/230B. In one embodiment, access to the memory array 200 by the various peripheral circuits is implemented in a symmetric fashion, on opposite sides of the array, so that the densities of access lines and circuitry on each side are reduced by half. The read/write circuits 230A/230B, in a further embodiment, include multiple sense blocks 250 which allow a page of memory cells to be read or programmed in parallel.

The memory array 200, in various embodiments, is addressable by word lines via row decoders 240A/240B and by bit lines via column decoders 242A/242B. In some embodiments, a controller 244 is included in the same memory device 210 (e.g., a removable storage card or package) as the one or more memory die 212. Commands and data are transferred between the host and controller 244 via lines 232 and between the controller and the one or more memory die 212 via lines 234. One implementation can include multiple chips 212.

Die controller 220, in one embodiment, cooperates with the read/write circuits 230A/230B to perform memory operations on the memory array 200. The die controller 220, in certain embodiments, includes a state machine 222, and an on-chip address decoder 224.

The state machine 222, in one embodiment, provides chip-level control of memory operations. The on-chip address decoder 224 provides an address interface to convert between the address that is used by the host or a memory controller to the hardware address used by the decoders 240A, 240B, 242A, 242B.

In one embodiment, one or any combination of die controller 220, routing reduction component 150, decoder circuit 224, state machine circuit 222, decoder circuit 242A, decoder circuit 242B, decoder circuit 240A, decoder circuit 240B, read/write circuits 230A, read/write circuits 230B, and/or controller 244 can be referred to as one or more managing circuits.

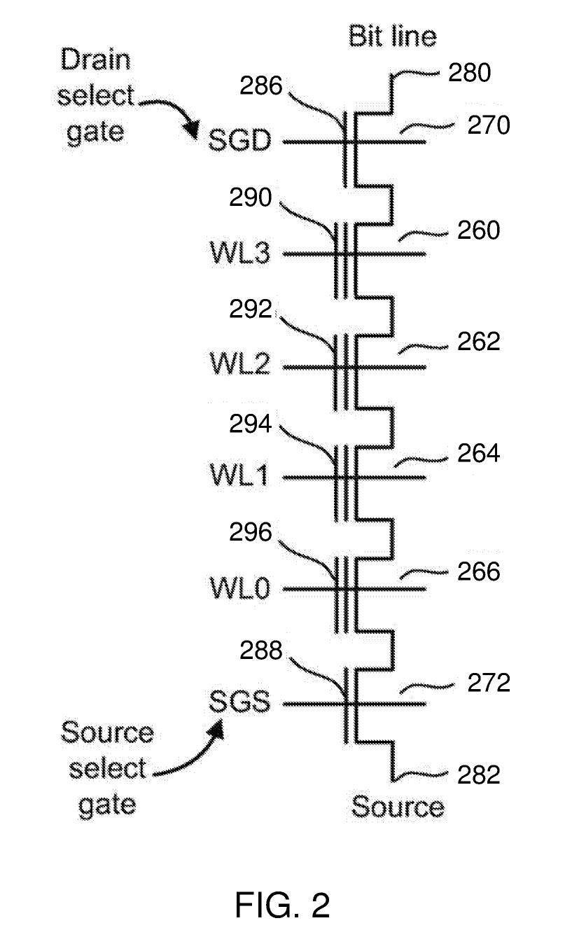

FIG. 2 depicts one embodiment of a NAND string comprising a plurality of storage elements. The NAND string depicted in FIG. 2, in some embodiments, includes four transistors 260, 262, 264, 266 connected in series and located between a first select transistor 270 and a second select transistor 272. In some embodiments, a transistor 260, 262, 264, 266 includes a control gate and a floating gate. A control gate 290, 292, 294, 296, in one embodiment, is connected to, or comprises a portion of, a word line. In a further embodiment, a transistor 260, 262, 264, 266 is a storage element, storage cell, or the like, also referred to as a memory cell. In some embodiments, a storage element may include multiple transistors 260, 262, 264, 266.

The first select transistor 270, in some embodiments, gates/connects the NAND string connection to a bit line 280 via a drain select gate SGD. The second select transistor 272, in certain embodiments, gates/connects the NAND string connection to a source line 282 via a source select gate SGS. The first select transistor 270, in a further embodiment, is controlled by applying a voltage to a corresponding select gate 286. The second select transistor 272, in some embodiments, is controlled by applying a voltage to corresponding select gate 288.

As shown in FIG. 2, the source line 282, in one embodiment, is connected to the sources of each transistor/storage cell 260, 262, 264, 266 in the NAND string. The NAND string, in some embodiments, may include some storage elements 260, 262, 264, 266 that have been programmed and some storage elements 260, 262, 264, 266 that have not been programmed. As described in more detail below, the routing reduction component 150 controls switch gate voltages used for sensing data for the storage elements 260, 262, 264, 266 (e.g., a read voltage, read current, and/or another read level). The duration of the switch gate voltages may be controlled based on a voltage at a routing line for the storage elements 260, 262, 264, 266.

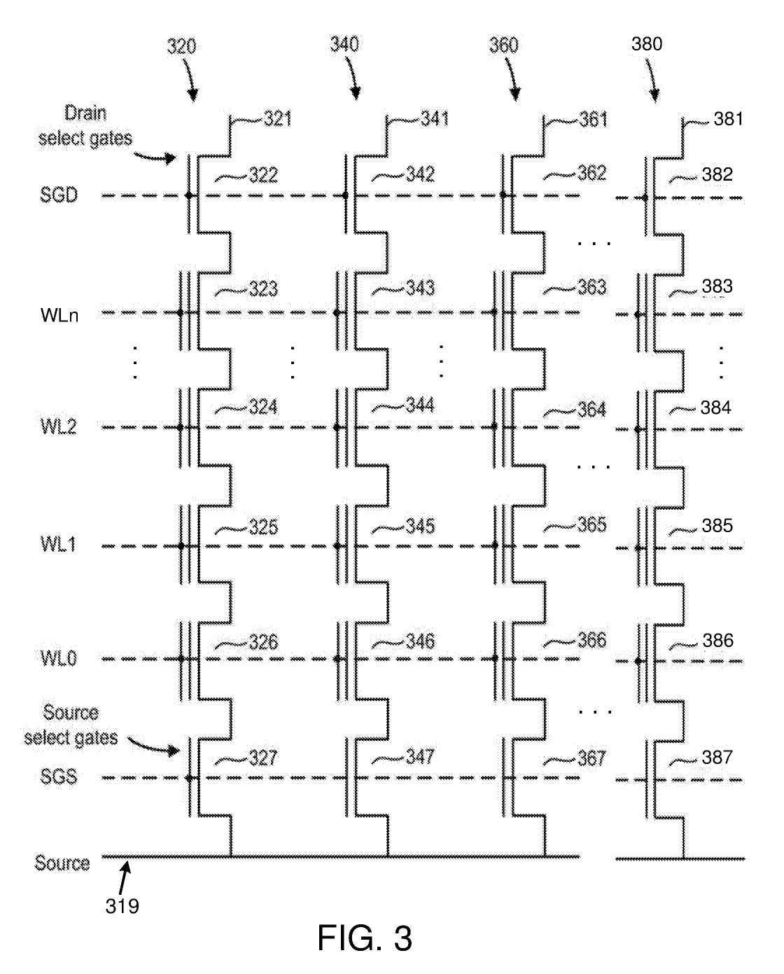

FIG. 3 is a circuit diagram depicting a plurality of NAND strings 320, 340, 360, 380. An architecture for a flash memory system using a NAND structure may include several NAND strings 320, 340, 360, 380. For example, FIG. 3 illustrates NAND strings 320, 340, 360, 380 in a memory array 200 that includes multiple NAND strings 320, 340, 360, 380. In the depicted embodiment, each NAND string 320, 340, 360, 380 includes drain select transistors 322, 342, 362, 382, source select transistors 327, 347, 367, 387, and storage elements 323-326, 343-346, 363-366, 383-386. While four storage elements 323-326, 343-346, 363-366, 383-386 per NAND string 320, 340, 360, 380 are illustrated for simplicity, some NAND strings 320, 340, 360, 380 can include any number of storage elements, e.g., thirty-two, sixty-four, or the like storage elements.

NAND strings 320, 340, 360, 380, in one embodiment, are connected to a source line 319 by source select transistors 327, 347, 367, 387. A selection line SGS may be used to control the source side select transistors. The various NAND strings 320, 340, 360, 380, in one embodiment, are connected to bit lines 321, 341, 361, 381 by drain select transistors 322, 342, 362, 382. The drain select transistors 322, 342, 362, 382 may be controlled by a drain select line SGD. In some embodiments, the select lines do not necessarily need to be in common among the NAND strings 320, 340, 360, 380; that is, different select lines can be provided for different NAND strings 320, 340, 360, 380.

As described above, each word line WL0-WLn comprises one or more storage elements 323-383, 324-384, 325-385, 326-386. In the depicted embodiment, each bit line 321, 341, 361, 381 and the respective NAND string 320, 340, 360, 380 comprise the columns of the memory array 200, storage block, erase block, or the like. The word lines WL0-WLn, in some embodiments, comprise the rows of the memory array 200, storage block, erase block, or the like. Each word line WL0-WLn, in some embodiments, connects the control gates of each storage element 323-383, 324-384, 325-385, 326-386 in a row. Alternatively, the control gates may be provided by the word lines WL0-WLn themselves. In some embodiments, a word line WL0-WLn may include tens, hundreds, thousands, millions, or the like of storage elements 323-383, 324-384, 325-385, 326-386.

In one embodiment, each storage element 323-326, 343-346, 363-366, 383-386 is configured to store data. For example, when storing one bit of digital data, the range of possible threshold voltages (“VTH”) of each storage element 323-326, 343-346, 363-366, 383-386 may be divided into two ranges which are assigned logical data “1” and “0.” In one example of a NAND type flash memory, the VTH may be negative after the storage elements 323-326, 343-346, 363-366, 383-386 are erased, and defined as logic “1.” In one embodiment, the VTH after a program operation is positive and defined as logic “0.”

When the VTH is negative and a read is attempted, in some embodiments, storage elements 323-326, 343-346, 363-366, 383-386 will turn on to indicate logic “1” is being stored. When the VTH is positive and a read operation is attempted, in a further embodiment, a storage element will not turn on, which indicates that logic “0” is stored. Each storage element 323-383, 324-384, 325-385, 326-386 may also store multiple levels of information, for example, multiple bits of digital data. In such an embodiment, the range of VTH value is divided into the number of levels of data. For example, if four levels of information can be stored in each storage element 323-326, 343-346, 363-366, 383-386, there will be four VTH ranges assigned to the data values “11”, “10”, “01”, and “00.”

In one example of a NAND type memory, the VTH after an erase operation may be negative and defined as “11.” Positive VTH values may be used for the states of “10”, “01”, and “00.” In one embodiment, the specific relationship between the data programmed into the storage elements 323-326, 343-346, 363-366, 383-386 and the threshold voltage ranges of the storage elements 323-326, 343-346, 363-366, 383-386 depends upon the data encoding scheme adopted for the storage elements 323-326, 343-346, 363-366, 383-386.

In some embodiments, temperature compensation used for sensing data on the storage elements 323-326, 343-346, 363-366, 383-386 may be noisy resulting in reduced sensing accuracy. In such an embodiment, the routing reduction component 150 may be a part of one or more of the storage elements 323-326, 343-346, 363-366, 383-386 to reduce signal routing.

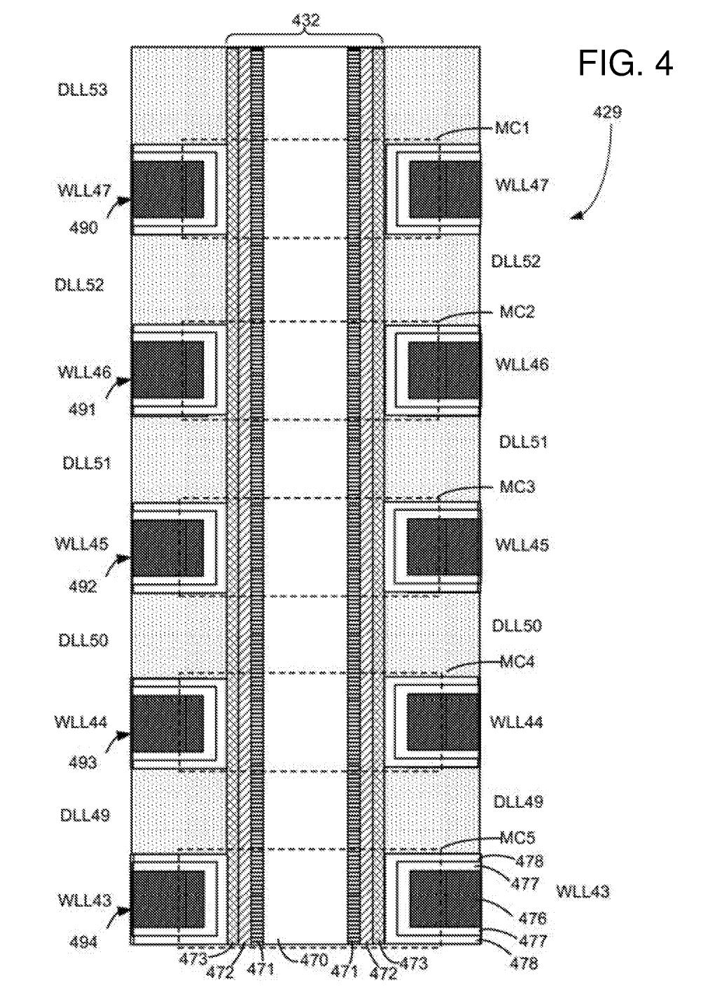

FIG. 4 illustrates one embodiment of a cross-sectional view of a 3D, vertical NAND flash memory structure 429 or string 429. In one embodiment, the vertical column 432 is round and includes four layers; however, in other embodiments more or less than four layers can be included and other shapes can be used (e.g., a “U” shape instead of an “I” shape or the like). In one embodiment, a vertical column 432 includes an inner core layer 470 that is made of a dielectric, such as SiO2. Other materials can also be used. Surrounding inner core 470 is polysilicon channel 471. Materials other than polysilicon can also be used. Note that it is the channel 471 that connects to the bit line. Surrounding channel 471 is a tunneling dielectric 472. In one embodiment, tunneling dielectric 472 has an ONO structure. Surrounding tunneling dielectric 472 is a shared charge trapping layer 473, such as (for example) Silicon Nitride. Other materials and structures can also be used. The technology described herein is not limited to any particular material or structure.

FIG. 4 depicts dielectric layers DLL49, DLL50, DLL51, DLL52 and DLL53, as well as word line layers WLL43, WLL44, WLL45, WLL46, and WLL47. Each of the word line layers includes a word line region 476 surrounded by an aluminum oxide layer 477, which is surrounded by a blocking oxide (SiO₂) layer 478. The physical interaction of the word line layers with the vertical column forms the memory cells. Thus, a memory cell, in one embodiment, comprises channel 471, tunneling dielectric 472, charge trapping layer 473 (e.g., shared with other memory cells), blocking oxide layer 478, aluminum oxide layer 477 and word line region 476. In some embodiments, the blocking oxide layer 478 and aluminum oxide layer 477, may be replaced by a single layer of material with insulating properties or by more than 2 layers of different material with insulating properties. Furthermore, the materials used are not limited to silicon dioxide (SiO₂) or aluminum oxide. For example, word line layer WLL47 and a portion of vertical column 432 comprise a memory cell MC1. Word line layer WLL46 and a portion of vertical column 432 comprise a memory cell MC2. Word line layer WLL45 and a portion of vertical column 432 comprise a memory cell MC3. Word line layer WLL44 and a portion of vertical column 432 comprise a memory cell MC4. Word line layer WLL43 and a portion of vertical column 432 comprise a memory cell MC5. In other architectures, a memory cell may have a different structure; however, the memory cell would still be the storage unit.

When a memory cell is programmed, electrons are stored in a portion of the charge trapping layer 473 which is associated with the memory cell. These electrons are drawn into the charge trapping layer 473 from the channel 471, through the tunneling dielectric 472, in response to an appropriate voltage on word line region 476. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as gate induced drain leakage (GIDL).

Storage cells in the same location or position in different memory structures 429 (e.g., different NAND strings 429) on different bit lines, in certain embodiments, may be on the same word line. Each word line may store one page of data, such as when 1-bit of data is stored per cell (SLC); two pages of data, such as when 2-bits of data are stored per cell (MLC); three pages of data, such as when 3-bits of data are stored per cell (TLC); four pages of data, such as when 4-bits of data are stored per cell (QLC); or another number of pages of data.

In the depicted embodiment, a vertical, 3D NAND flash memory structure 429 comprises an “I” shaped memory structure 429. In other embodiments, a vertical, 3D NAND flash memory structure 429 may comprise a “U” shaped structure, or may have another vertical and/or stacked architecture. In certain embodiments, four sets of strings 429 (e.g., four sets of 48 word lines, or another predefined number of word lines) may form an erase block, while in other embodiments, fewer or more than four sets of strings 429 may form an erase block. As may be appreciated, any suitable number of storage cells may be part of a single string 429. In one embodiment, a single string 429 includes 48 storage cells.

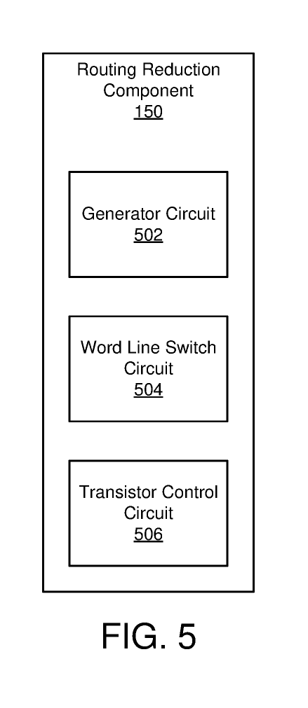

FIG. 5 depicts one embodiment of a routing reduction component 150. The routing reduction component 150 may be substantially similar to the routing reduction component 150 described above with regard to FIGS. 1A, 1B, 2, and/or 3. In general, as described above, the routing reduction component 150 generates switch gate voltages for two or more word line switches, supplies the switch gate voltages to the two or more word line switches, and supplies select gate voltages to two or more select gates. Accordingly, the routing reduction component 150 may facilitate reducing routing signals. In certain embodiments, by reducing a number of routing signals, power may be reduced at least because fewer routing signals are charged to a higher voltage. In the depicted embodiment, the routing reduction component 150 includes a generator circuit 502, a word line switch circuit 504, and a transistor control circuit 506.

In various embodiments, the generator circuit 502 generates switch gate voltages for two or more word line switches. In such embodiments, the two or more word line switches may be on opposite sides of an array of memory elements (e.g., the memory array 200) and may be for coupling word line voltages to word lines. The switch gate voltages may be generated in any suitable manner, such as by using a level shifter, an inverter, a power source, and so forth. In some embodiments, the switch gate voltages may be approximately 0 volts to turn off (e.g., inhibit, deactivate) each of the two or more word line switches. In certain embodiments, the switch gate voltages may be approximately 25 volts (e.g., in a range between 20 volts and 35 volts) to turn on (e.g., enable, activate) each of the two or more word line switches. In one embodiment, in response to a word line switch being turned on, voltage from a control gate may be passed through the word line switch to a word line.

In certain embodiments, the word line switch circuit 504 supplies switch gate voltages to two or more word line switches. In some embodiments, the word line switch circuit 504 supplies the switch gate voltages to the two or more word line switches using routing circuitry that directly electronically couples the generator circuit 502 to gates of the two or more word line switches.

In some embodiments, the transistor control circuit 506 supplies select gate voltages to two or more select gates. In various embodiments, the transistor control circuit 506 supplies the select gate voltages to the two or more select gates using routing circuitry that directly electronically couples a generator that generates the select gate voltages to the two or more select gates. In certain embodiments, the two or more select gates control select gate drain transistors.

In some embodiments, the select gate voltages may be approximately 0 volts to turn off (e.g., inhibit, deactivate) a select transistor used to control a select gate drain transistor. In certain embodiments, the select gate voltages may be approximately 2.5 volts (e.g., in a range between 1.5 volts and 3.5 volts) to turn on (e.g., enable, activate) a select transistor used to control a select gate drain transistor. In one embodiment, in response to a select transistor being turned on, voltage from VSS may be passed through the select transistor to a select gate drain transistor.

In various embodiments, the select gate voltages are different from the switch gate voltages. For example, the select gate voltages may be an inverse polarity from the switch gate voltages. As used herein, an inverse polarity voltage may mean that if one voltage is a logic high, the other voltage is a logic low. For example, if the select gate voltages are a logic high, the switch gate voltages may be a logic low. As another example, if the switch gate voltages are a logic high, the select gate voltages may be a logic low.

In certain embodiments, the select gate voltages and the switch gate voltages are both based on a routing line voltage on a routing line that extends across an array of memory elements (e.g., the memory array 200). Being based on the routing line voltage may mean that the routing line voltage is adjusted in order to obtain the select gate voltages and the switch gate voltages. It should be noted that the routing line voltage may be adjusted in one manner to obtain the select gate voltages and may be adjusted in a different manner to obtain the switch gate voltages. For example, the routing line voltage may be voltage shifted up and/or down to obtain the switch gate voltages and the routing line voltage may be inverted to have an inverse polarity to obtain the select gate voltages. As another example, the routing line voltage may be unchanged to obtain the select gate voltages and the routing line voltage may be inverted to have an inverse polarity to obtain the switch gate voltages.

In various embodiments, the switch gate voltages are greater than 20 volts (e.g., logic high) and the select gate voltages are less than 3 volts (e.g., logic low). In certain embodiments, the switch gate voltages are less than 3 volts (e.g., logic low) and the select gate voltages are greater than 20 volts (e.g., logic high). In some embodiments, the switch gate voltages are less than 3 volts (e.g., logic low) and the select gate voltages are less than 3 volts (e.g., logic high). In various embodiments, the routing line voltage on the routing line is less than 3 volts. In such embodiments, the routing line voltage may be less than 3 volts so that a high voltage does not have to be carried on the routing line. By reducing a voltage carried on the routing line, interference with other components may be reduced and power consumption may be reduced. Furthermore, by reducing the voltage carried on the routing line a performance speed may be increased because it may be faster to charge the routing line to a lower voltage than to a higher voltage. Moreover, using only the routing line to generate the switch gate voltages and the select gate voltages, space may be reduced because only one routing line is used instead of two or more.

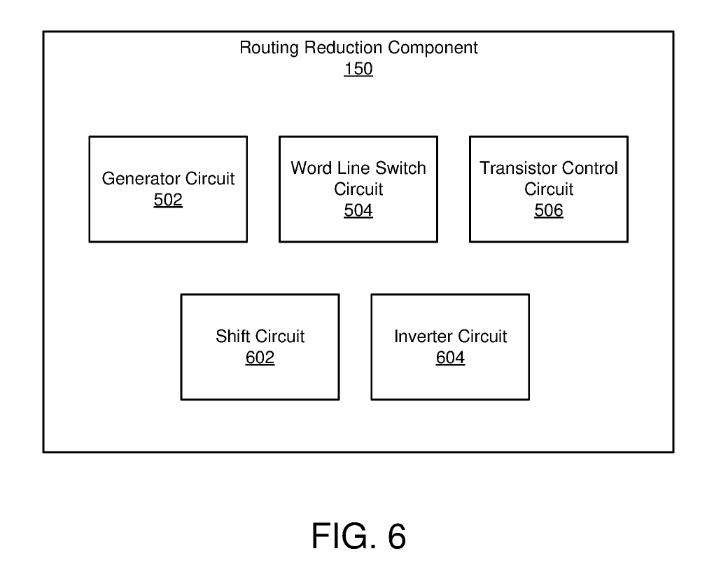

Turning to FIG. 6, a further embodiment of a routing reduction component 150 is illustrated. The routing reduction component 150 may be substantially similar to the routing reduction component 150 described above with regard to FIGS. 1A, 1B, 2, 3, and/or 5. In the depicted embodiment, the routing reduction component 150 includes the generator circuit 502, the word line switch circuit 504, and the transistor control circuit 506 and further includes a shift circuit 602 and an inverter circuit 604.

In one embodiment, the shift circuit 602 is configured to increase and/or decrease a routing line voltage. For example, in certain embodiments, the shift circuit 602 may be configured to increase the routing line voltage and produce switch gate voltages in response to the routing line voltage indicating a logic high value. As another example, in various embodiments, the shift circuit 602 may be configured to decrease the routing line voltage and produce switch gate voltages in response to the routing line voltage indicating a logic low value.

In certain embodiments, the inverter circuit 604 is configured to invert (e.g., invert a polarity, invert from a logic high to a logic low, invert from a logic low to a logic high) a routing line voltage to produce select gate voltages. In some embodiments, the inverter circuit 604 is configured to invert the routing line voltage to produce an inverted voltage. In one embodiment, the shift circuit 602 may be configured to increase the inverted voltage and produce the switch gate voltages in response to the inverted voltage indicating a logic high value.

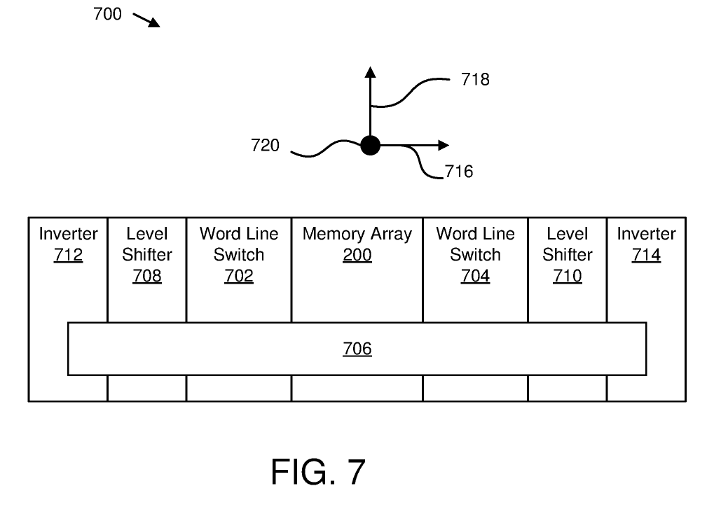

FIG. 7 is a schematic block diagram illustrating a further embodiment of a system 700 for reduced routing signals. The system 700 includes the memory array 200 (e.g., an array of storage elements), a first word line switch 702 on one side of the memory array 200, a second word line switch 704 on a different (e.g., opposite) side of the memory array 200, a block select routing line 706, a first level shifter 708, a second level shifter 710, a first inverter 712, and a second inverter 714. The block select routing line 706 extends along an x-axis 716 over the first word line switch 702, the second word line switch 704, and the memory array 200 (e.g., in a metal layer or other conductive layer above and in a different plane than the memory array 200, between the different/opposite sides of the memory array 200, or the like). A y-axis 718 and a z-axis 720 are show for perspective relative to the x-axis 716. The z-axis 720 extends into the page. In one embodiment, the first level shifter 708 is coupled to one end of the block select routing line 706 and the second level shifter 710 is coupled to an opposite end of the block select routing line 706. The first and second level shifters 708 and 710 may operate in a similar manner to the shift circuit 602. In certain embodiments, the first inverter 712 is coupled to one end of the block select routing line 706 and the second inverter 714 is coupled to an opposite end of the block select routing line 706. The first and second inverters 712 and 714 may operate in a similar manner to the inverter circuit 604.

In various embodiments, a block select gate voltage may be supplied to word line switch gates of the first and second word line switches 702 and 704 based on a routing line voltage on the block select routing line 706 (e.g., by shifting and/or inverting the routing line voltage). In certain embodiments, an inverse polarity block select gate voltage may be supplied to select gates of two or more transistors based on the routing line voltage on the block select routing line 706 (e.g., by shifting and/or inverting the routing line voltage).

In one embodiment, the first and second level shifters 708 and 710 increase the routing line voltage carried by the block select routing line 706 to produce the block select gate voltage in response to the routing line voltage indicating a logic high. In certain embodiments, the routing line voltage is increased from less than 3 volts to greater than 25 volts in response to the routing line voltage indicating a logic high.

In various embodiments, the first and second inverters 712 and 714 may invert the routing line voltage carried by the block select routing line 706 to produce the inverse polarity block select gate voltage. In some embodiments, the first and second inverters 712 and 714 may invert the routing line voltage carried by the block select routing line 706 to produce an inverted voltage. In certain embodiments, the first and second level shifters 708 and 710 may increase the inverted voltage to produce the inverse polarity block select gate voltage in response to the inverted voltage indicating a logic high. In some embodiments, the inverse polarity block select gate voltage is increased from less than 3 volts to greater than 25 volts in response to the inverted voltage indicating a logic high.

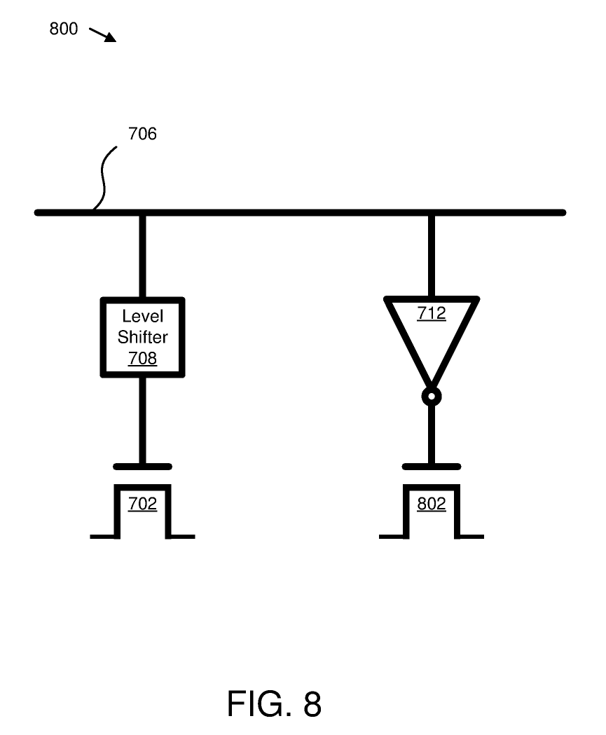

FIG. 8 is a circuit diagram illustrating one embodiment of a circuit 800 for reduced routing signals. In the illustrated embodiment, the circuit 800 includes the block select routing line 706 that carries a logic level (e.g., logic high, logic low) corresponding to a block select gate voltage (e.g., BLKSEL). However, a voltage carried by the block select routing line 706 for a logic high is substantially lower than a logic high voltage used by the first word line switch gate 702. Accordingly, the first level shifter 708 may increase the voltage carried by the block select routing line 706 to the logic high voltage used by the first word line switch gate 702. Moreover, the voltage carried by the block select routing line 706 is an inverse polarity (e.g., logic high instead of logic low, logic low instead of logic high) for what is used by a select transistor 802. Accordingly, the first inverter 712 may invert the polarity of the voltage carried by the block select routing line 706 before the voltage is provided to the select transistor 802.

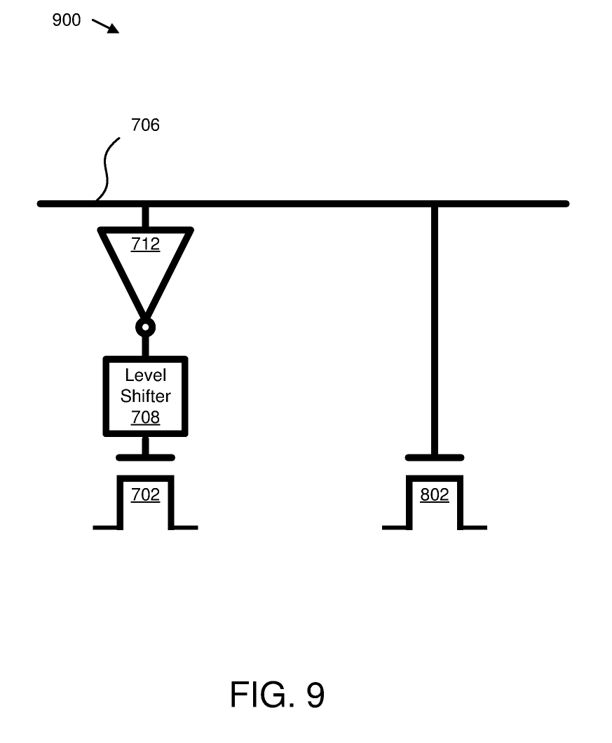

FIG. 9 is a circuit diagram illustrating another embodiment of a circuit 900 for reduced routing signals. In the illustrated embodiment, the circuit 900 includes the block select routing line 706 that carries a logic level (e.g., logic high, logic low) corresponding to an inverse polarity block select gate voltage (e.g., BLKSELn). Accordingly, the first inverter 712 may invert the polarity of the voltage carried by the block select routing line 706 and, in response to the voltage indicating a logic high, the first level shifter 708 may increase the voltage carried by the block select routing line 706 to the logic high voltage used by the first word line switch gate 702. In response to the inverted voltage carried by the block select routing line 706 indicating a logic low, the inverted voltage may be directly supplied to the first word line switch gate 702. Moreover, the voltage carried by the block select routing line 706 may be directly provided to the select transistor 802.

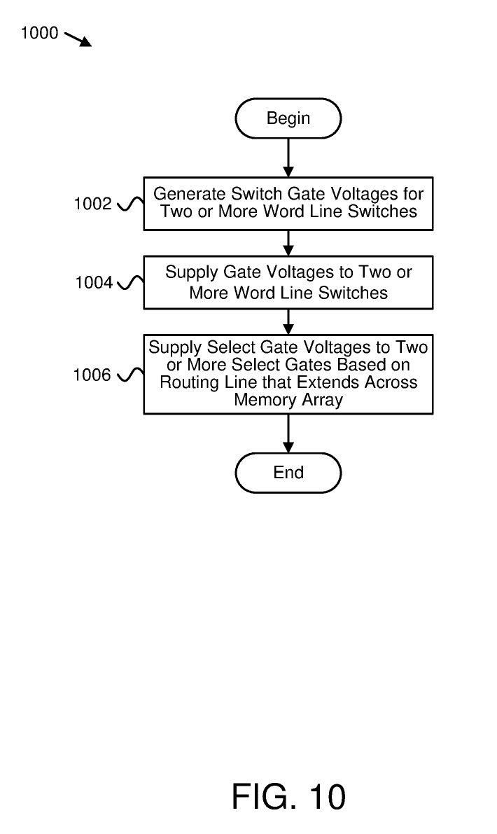

FIG. 10 is a schematic flow chart diagram illustrating one embodiment of a method 1000 for reduced routing signals. The method 1000 begins, and the word line switch circuit 504 supplies 1002 a block select gate voltage to a plurality of word line switch gates based on a routing line voltage on a single routing line (e.g., the block select routing line 706) that extends across an array of memory elements (e.g., the memory array 200). Moreover, the transistor control circuit 506 supplies 1004 an inverse polarity block select gate voltage to a plurality of select gates without a routing line separate from the single routing line, and the method 1000 ends.

A means for supplying a block select gate voltage to a plurality of word line switch gates based on a routing line voltage on a single routing line that extends across an array of memory elements, in various embodiments, may include one or more of a routing reduction component 150, a word line switch circuit 504, a non-volatile memory device 120, a non-volatile memory medium controller 126, a non-volatile memory device interface 139, a host computing device 110, a device driver, a controller (e.g., a device driver, or the like) executing on a host computing device 110, a processor 111, an FPGA, an ASIC, other logic hardware, and/or other executable code stored on a computer readable storage medium. Other embodiments may include similar or equivalent means for supplying a block select gate voltage to a plurality of word line switch gates based on a routing line voltage on a single routing line that extends across an array of memory elements.

A means for supplying an inverse polarity block select gate voltage to a plurality of select gates without a routing line separate from the single routing line, in certain embodiments, may include one or more of a routing reduction component 150, a transistor control circuit 506, a non-volatile memory device 120, a non-volatile memory medium controller 126, a non-volatile memory device interface 139, a host computing device 110, a device driver, a controller (e.g., a device driver, or the like) executing on a host computing device 110, a processor 111, an FPGA, an ASIC, other logic hardware, and/or other executable code stored on a computer readable storage medium. Other embodiments may include similar or equivalent means for supplying an inverse polarity block select gate voltage to a plurality of select gates without a routing line separate from the single routing line.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. An apparatus comprising:
a generator circuit that generates switch gate voltages for two or more word line switches, wherein the two or more word line switches are on opposite sides of an array of memory elements and are for coupling word line voltages to word lines;
a word line switch circuit that supplies the switch gate voltages to the two or more word line switches; and
a transistor control circuit that supplies select gate voltages to two or more select gates, wherein the two or more select gates control select gate drain transistors, the select gate voltages are different from the switch gate voltages, the select gate voltages and the switch gate voltages are both based on a routing line voltage on a routing line that extends across the array of memory elements in a first direction from a first side of the memory array to a second side of the memory array opposite the first side, the routing line voltage on the routing line is the same at the first side of the memory array and the second side of the memory array, and the same routing line voltage is used to produce the select gate voltages and the switch gate voltages on the first side of the memory array and the second side of the memory array.

2. The apparatus of claim 1, further comprising a shift circuit that increases the routing line voltage and produces the switch gate voltages in response to the routing line voltage indicating a logic high value.

3. The apparatus of claim 2, further comprising an inverter circuit that inverts the routing line voltage to produce the select gate voltages.

4. The apparatus of claim 1, further comprising an inverter circuit that inverts the routing line voltage to produce an inverted voltage.

5. The apparatus of claim 4, further comprising a shift circuit that increases the inverted voltage and produces the switch gate voltages in response to the inverted voltage indicating a logic high value.

6. The apparatus of claim 1, wherein the switch gate voltages are greater than 20 volts and the select gate voltages are less than 3 volts.

7. The apparatus of claim 1, wherein the switch gate voltages are less than 3 volts and the select gate voltages are greater than 20 volts.

8. The apparatus of claim 1, wherein the switch gate voltages are less than 3 volts and the select gate voltages are less than 3 volts.

9. The apparatus of claim 1, wherein the routing line voltage on the routing line is less than 3 volts.

10. A system comprising:
an array of storage elements;
two or more word line switches disposed on different sides of the array;
a block select routing line extending over the two or more word line switches and the array in a first direction in a different plane than the array and between the different sides of the array, wherein a routing line voltage on the block select routing line is the same on the different sides of the array; and
two or more level shifters coupled to opposite ends of the block select routing line, wherein:
a block select gate voltage is supplied to word line switch gates of the two or more word line switches based on the routing line voltage on the block select routing line, wherein the routing line voltage is used to produce the block select gate voltage; and
an inverse polarity block select gate voltage is supplied to select gates of two or more transistors based on the routing line voltage on the block select routing line.

11. The system of claim 10, wherein the two or more level shifters increase the routing line voltage carried by the block select routing line to produce the block select gate voltage in response to the routing line voltage indicating a logic high.

12. The system of claim 11, wherein the routing line voltage is increased from less than 3 volts to greater than 25 volts in response to the routing line voltage indicating a logic high.

13. The system of claim 12, further comprising two or more inverters, wherein the two or more inverters invert the routing line voltage carried by the block select routing line to produce the inverse polarity block select gate voltage.

14. The system of claim 10, further comprising two or more inverters, wherein the two or more inverters invert the routing line voltage carried by the block select routing line to produce an inverted voltage.

15. The system of claim 14, wherein the two or more level shifters increase the inverted voltage to produce the inverse polarity block select gate voltage in response to the inverted voltage indicating a logic high.

16. The system of claim 15, wherein the inverse polarity block select gate voltage is increased from less than 3 volts to greater than 25 volts in response to the inverted voltage indicating a logic high.

17. The system of claim 10, wherein the block select gate voltage is greater than 25 volts and the inverse polarity block select gate voltage is less than 3 volts.

18. The system of claim 10, wherein the block select gate voltage is less than 3 volts and the inverse polarity block select gate voltage is greater than 25 volts.

19. The system of claim 10, wherein the routing line voltage carried by the block select routing line is less than 3 volts.

20. An apparatus comprising:
means for supplying a block select gate voltage to a plurality of word line switch gates based on a routing line voltage on a single routing line that extends across an array of memory elements in a first direction from a first side of the array to a second side of the array opposite the first side, wherein a first word line switch gate of the plurality of word line switch gates is on the first side of the array, a second word line switch gate of the plurality of word line switch gates is on the second side of the array, the routing line voltage on the single routing line is the same at the first side of the array and the second side of the array, and the routing line voltage is used to produce the block select gate voltage; and
means for supplying an inverse polarity block select gate voltage to a plurality of select gates without a routing line separate from the single routing line wherein the routing line voltage is used to produce the inverse polarity block select gate voltage.
